(19) United States
(12) Patent Application Publication
(10) Pub. No.: US 2024/0170308 A1
(43) Pub. Date: May 23, 2024

(54) APPARATUS FOR PREHEATING A SUBSTRATE

(71) Applicant: SAMSUNG ELECTRONICS CO., LTD., Suwon-si (KR)

(72) Inventors: Joohee KIM, Suwon-si (KR); Youngjae JEON, Suwon-si (KR); Jaehyun CHO, Suwon-si (KR); Yihwan KIM, Suwon-si (KR)

(21) Appl. No.: 18/215,258

(22) Filed: Jun. 28, 2023

(30) Foreign Application Priority Data
Nov. 21, 2022 (KR) 10-2022-0156040

(51) Int. Cl. H01L 21/67

(52) U.S. Cl. CPC H01L 21/67115; H01L 21/67017; H01J 37/3171

(57) ABSTRACT

An apparatus for preheating a substrate includes a preheating chamber, a cooling plate, a heater, an isolation plate, a gas supplier and a gas discharger. The preheating chamber may be configured to receive the substrate. The cooling plate may be arranged on an upper surface of the preheating chamber. The heater may be arranged between the cooling plate and the substrate to heat the substrate. The isolation plate may be arranged between the cooling plate and the substrate to form a first space between the preheating chamber and the isolation plate and a second space between the cooling plate and the isolation plate. The gas supplier may be configured to individually supply a vent gas to the first space and the second space. The gas discharge may be configured to individually supply vacuum to the first space and the second space.

### CROSS-REFERENCE TO RELATED APPLICATION

This application claims priority under 35 USC § 119 to Korean Patent Application No. 10-2022-0156040, filed on Nov. 21, 2022, in the Korean Intellectual Property Office (KIPO), the contents of which are herein incorporated by reference in their entirety.

### BACKGROUND

### 1. Field

Example embodiments relate to an apparatus for preheating a substrate. More particularly, example embodiments relate to an apparatus for preheating a semiconductor substrate before an ion implantation process.

### 2. Description of the Related Art

Generally, a semiconductor substrate may be preheated using a preheating apparatus before an ion implantation process for implanting ions into the semiconductor substrate. The preheating apparatus may preheat the semiconductor substrate using a lamp heater in a preheating chamber. Further, the preheating apparatus may include a cooling plate for controlling a temperature of the lamp heater.

### SUMMARY

According to example embodiments, there may be provided an apparatus for preheating a substrate, including a preheating chamber, a cooling plate, a heater, an isolation plate, a gas supplier and a gas discharger. The preheating chamber may be configured to receive the substrate. The cooling plate may be arranged on an upper surface of the preheating chamber. The heater may be arranged between the cooling plate and the substrate to heat the substrate. The isolation plate may be arranged between the cooling plate and the substrate to form a first space between the preheating chamber and the isolation plate and a second space between the cooling plate and the isolation plate. The gas supplier may be configured to individually supply a vent gas to the first space and the second space. The gas discharge may be configured to individually supply vacuum to the first space and the second space.

According to example embodiments, there may be provided an apparatus for preheating a substrate, including a preheating chamber, a cooling plate, a heater, an isolation plate, a gas supplier and a gas discharger. The preheating chamber may be configured to receive the substrate before an ion implantation process. The cooling plate may be arranged on an upper surface of the preheating chamber. The heater may be arranged between the cooling plate and the substrate to heat the substrate. The isolation plate may be arranged between the cooling plate and the substrate. The isolation plate may be combined with an edge portion of a lower surface of the cooling plate to form a first space between the preheating chamber and the isolation plate and a second space between the cooling plate and the isolation plate. The gas supplier may be configured to individually supply a vent gas to the first space and the second space. The gas discharge may be configured to individually supply vacuum to the first space and the second space. The gas supplier may include a main gas line, at least one first gas line and at least one second gas line. The main gas line may be configured to supply the vent gas to the preheating chamber. The first gas line may be connected between the main gas line and the first space. The second gas line may be connected between the main gas line and the second space. The gas discharger may include a main exhaust line, at least one first exhaust line and at least one second exhaust line. The main exhaust line may be configured to supply the vacuum to the preheating chamber. The first exhaust line may be connected between the main exhaust line and the first space. The second exhaust line may be connected between the main exhaust line and the second space.

According to example embodiments, there may be provided an apparatus for preheating a substrate, including a preheating chamber, a cooling plate, a lamp heater, an isolation plate, a first gas supplier, a second gas supplier, a first gas discharger and a second gas discharger. The preheating chamber may be configured to receive the substrate before an ion implantation process. The cooling plate may be arranged on an upper surface of the preheating chamber. The lamp heater may be arranged between the cooling plate and the substrate to heat the substrate. The isolation plate may be arranged between the cooling plate and the substrate. The isolation plate may include a combining portion combined with an edge portion of a lower surface of the cooling plate. The isolation plate may be configured to form a first space between the preheating chamber and the isolation plate and a second space between the cooling plate and the isolation plate. The first gas supplier may be configured to supply a vent gas to the first space. The second gas supplier may be configured to supply the vent gas to the second space. The first gas discharge may be configured to supply vacuum to the first space. The second gas discharger may be configured to supply the vacuum to the second space.

### BRIEF DESCRIPTION OF THE DRAWINGS

Features will become apparent to those of skill in the art by describing in detail exemplary embodiments with reference to the attached drawings, in which:

FIG. 1 is a perspective view illustrating an apparatus for preheating a substrate in accordance with example embodiments;

FIG. 2 is a cross-sectional view illustrating the apparatus in FIG. 1;

FIG. 3 is an enlarged cross-sectional view illustrating a gas supplier and a gas discharger of the apparatus in FIG. 2; and

FIG. 4 is a cross-sectional view illustrating an apparatus for preheating a substrate in accordance with example embodiments.

### DETAILED DESCRIPTION

Hereinafter, example embodiments will be explained in detail with reference to the accompanying drawings.

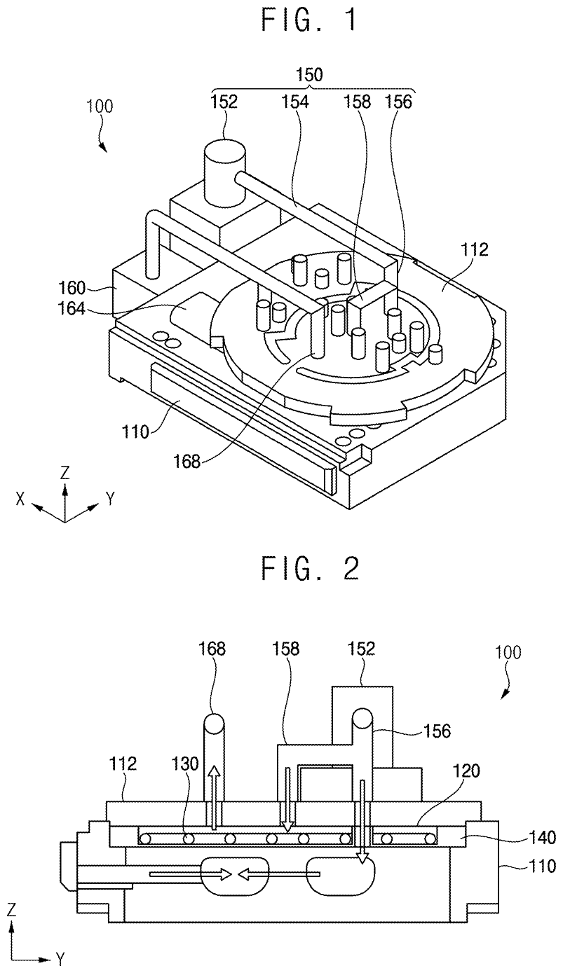

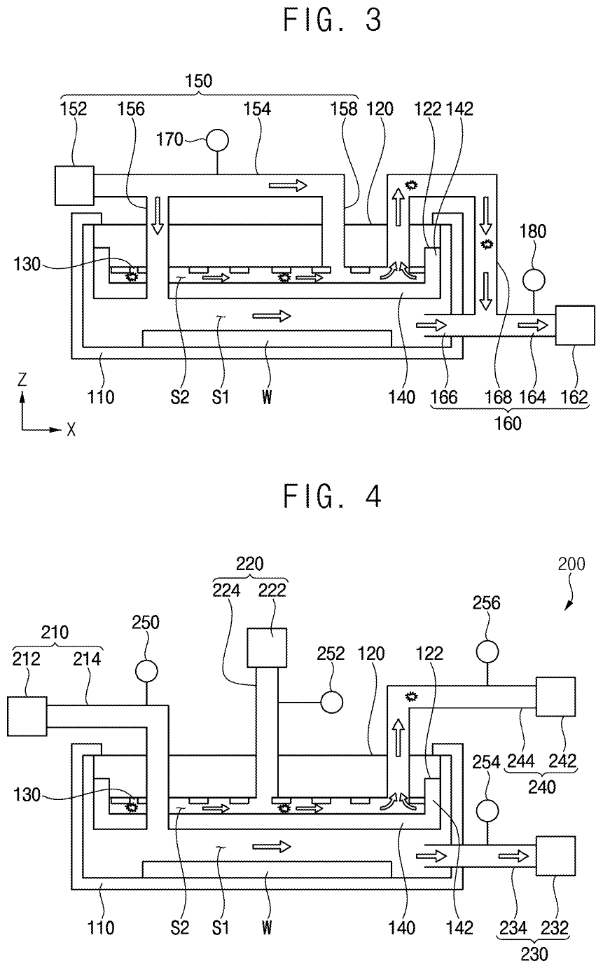

FIG. 1 is a perspective view illustrating an apparatus for preheating a substrate in accordance with example embodiments, FIG. 2 is a cross-sectional view of the apparatus in FIG. 1, and FIG. 3 is an enlarged cross-sectional view illustrating a gas supplier and a gas discharger of the apparatus in FIG. 2.

A preheating apparatus 100 for preheating a substrate W in accordance with example embodiments may be configured to preheat the substrate W before a process. The substrate W may include a semiconductor substrate, a glass substrate, etc. Particularly, the preheating apparatus 100 may preheat the substrate W before any one of semiconductor fabrication processes. For example, in order to reduce a time of an ion implantation process, the preheating apparatus 100 may preheat the semiconductor substrate W before the ion implantation process.

Referring to FIGS. 1 to 3, the preheating apparatus 100 may include a preheating chamber 110, a cooling plate 120, a heater 130, an isolation plate 140, a gas supplier 150, and a gas discharger 160.

The preheating chamber 110 may have an inner space configured to receive the semiconductor substrate W. The preheating chamber 110 may have an opened upper surface. A cover 112 may be arranged on the opened upper surface of the preheating chamber 110 to open/close the upper surface of the preheating chamber 110.

The cooling plate 120 may be arranged at an upper portion of the preheating chamber 110, e.g., on an upper surface of the preheating chamber 110. For example, the cooling plate 120 may be arranged on a lower surface of the cover 112, e.g., the cooling plate 120 may be arranged between an interior of the preheating chamber 110 and the lower surface of the cover 112 (i.e., a surface of the cover 112 facing the interior of the preheating chamber 110). The cooling plate 120 may cool the semiconductor substrate W in the preheating chamber 110 to prevent the semiconductor substrate W from being overheated. Thus, the cooling plate 120 may include a cooling passage through which a cooling agent may flow.

In example embodiments, the cooling plate 120 may have, e.g., a circular plate shape. For example, as illustrated in FIG. 3, the cooling plate 120 may include a combining groove 122. The combining groove 122 may be formed at an edge portion of a lower surface of the cooling plate 120. For example, the combining groove 122 may have an annular shape formed, e.g., continuously, along the edge portion of the lower surface of the cooling plate 120. In another example, the combining groove 122 may include a plurality of grooves formed at the edge portion of the lower surface of the cooling plate 120 by a uniform gap, e.g., at constant intervals.

The heater 130 may be arranged under the cooling plate 120. The heater 130 may preheat the semiconductor substrate W in the preheating chamber 110. When the semiconductor substrate W is overheated by the heater 130, the cooling plate 120 may cool the semiconductor substrate W. In example embodiments, the heater 130 may be arranged on the lower surface of the cooling plate 120, e.g., on a surface of the cooling plate 120 facing the bottom of the preheating chamber 110. For example, the heater 130 may include a lamp heater.

The isolation plate 140 may be arranged between the semiconductor substrate W and the heater 130, e.g., between the bottom of the preheating chamber 110 and the heater 130. The isolation plate 140 may prevent contaminants generated from the heater 130 from dropping to the semiconductor substrate W. In example embodiments, the isolation plate 140 may include, e.g., quartz.

In example embodiments, the isolation plate 140 may have, e.g., a circular plate shape. The isolation plate 140 may be arranged over the semiconductor substrate W. That is, the isolation plate 140 may be positioned over a bottom surface of the preheating chamber 110. Thus, a first space S1 may be formed, e.g., defined, between the isolation plate 140 and the bottom surface of the preheating chamber 110. Further, the isolation plate 140 may be positioned under the cooling plate 120. The isolation plate 140 may be spaced apart from the cooling plate 120 to form, e.g., define, a second space S2 between the isolation plate 140 and the cooling plate 120. That is, the isolation plate 140 may be positioned between the cooling plate 120 and the bottom of the preheating chamber 110 at a predetermined distance from each of the cooling plate 120 and the bottom of the preheating chamber 110 to divide the inner space of the preheating chamber 110 into the first space S1 and the second space S2.

Further, the isolation plate 140 may include a combining portion 142 combined with the combining groove 122 of the cooling plate 120. The combining portion 142 may vertically protrude from an edge portion of an upper surface of the isolation plate 140 toward the cooling plate 120, e.g., to be inserted into the combining groove 122 of the cooling plate 120. Because the combining portion 142 is inserted into the combining groove 122, the combining portion 142 may have a shape corresponding to, e.g., complementary with respect to, a shape of the combining groove 122. In example embodiments, because the combining groove 122 may have the annular shape, the combining portion 142 may also have an annular shape. Thus, the shape of the combining portion 142 may be determined in accordance with the shape of the combining groove 122. Alternatively, the cooling plate 120 may include a combining portion, and the isolation plate 140 may include a combining groove. For example, a seal, e.g., an O-ring, may be interposed between the combining groove 122 and the combining portion 142.

Therefore, the second space S2 may be defined by the lower surface of the cooling plate 120, the upper surface of the isolation plate 140 and an inner surface of the combining portion 142. The first space S1 may be defined by the bottom surface and an inner side surface of the preheating chamber 110 and the lower surface and an outer side surface of the isolation plate 140. The outer side surface of the isolation plate 140 may include an outer side surface of the combining portion 142.

Therefore, the combining portion 142 may be inserted into the combining groove 122 to, e.g., completely, isolate the first space S1 and the second space S2 from each other. That is, a fluid in the first space S1 may not be moved into the second space S2. Further, a fluid in the second space S2 may not be moved into the first space S1. In detail, the contaminants in the second space S2, e.g., particles generated by the heater 130, may not infiltrate into the first space S1. As a result, the semiconductor substrate W in the first space S1 may not be contaminated by the contaminants. The gas supplier 150 may be configured to individually, e.g., separately or

independently, supply a vent gas to, e.g., each of, the first space S1 and the second space S2, e.g., the gas supplier 150 may supply a vent gas to each of the first space S1 and the second space S2 through a separate line (pipe or conduit). The vent gas may include an inert gas, e.g., a nitrogen gas.

In detail, referring to FIGS. 1 and 3, the gas supplier 150 may include a vent gas tank 152, a main gas line 154, at least one first gas line 156, and at least one second gas line 158. The vent gas tank 152 may be configured to store the vent gas. The main gas line 154 may be extended from the vent gas tank 152 to the preheating chamber 110. For example, the main gas line 154 may be positioned over the preheating chamber 110. A manometer 170 for measuring a pressure of the vent gas may be arranged on the main gas line 154.

The first gas line 156 may be branched from the main gas line 154. The first gas line 156 may be connected to, e.g., in fluid communication with, the first space S1. For example, the first gas line 156 may be connected to the first space S1 through the cover 112, the cooling plate 120, and the isolation plate 140. That is, the first gas line 156 may be connected to the first space S1 via the second space S2, i.e., the first gas line 156 may extend through the second space S2 (while an interior of the first gas line 156 may be completely separated from the second space S2) to be connected to the first space S1. Thus, the vent gas may be introduced into the first space S1 through the first gas line 156. In another example, the first gas line 156 may be directly connected to the first space S1, not through the cooling plate 120, the second space S2, and the isolation plate 140. For example, the first gas line 156 may include a single line. In another example, the first gas line 156 may include at least two lines.

As discussed above, the first gas line 156 may be branched from the main gas line 154. Therefore, a pressure of the vent gas in the first gas line 156 may be substantially the same as a pressure of the vent gas in the main gas line 154. Thus, the pressure of the vent gas in the main gas line 154 and the first gas line 156 may be controlled using one, e.g., a single, manometer 170.

The second gas line 158 may be branched from the main gas line 154. The second gas line 158 may be connected to the second space S2. For example, the second gas line 158 may be connected to, e.g., in fluid communication with, the second space S2 through the cooling plate 120. Thus, the vent gas may be introduced into the second space S2 through the second gas line 158. In another example, the second gas line 158 may be directly connected to the second space S2, not through the cooling plate 120. For example, in example embodiments, the second gas line 158 may include a single line. In another example, the second gas line 158 may include at least two lines.

As discussed above, the second gas line 158 may be branched from the main gas line 154. Therefore, a pressure of the vent gas in the second gas line 158 may be substantially the same as a pressure of the vent gas in the main gas line 154. Thus, the pressure of the vent gas in the main gas line 154 and the second gas line 158 may be controlled using one manometer 170.

Further, because the first gas line 156 and the second gas line 158 are branched from the main gas line 154, a pressure difference between the first space S1 and the second space S2 may be offset, e.g., substantially minimized. Thus, a damage to the isolation plate 140, which may be potentially caused by the pressure difference between the first space S1 and the second space S2, may be prevented.

The gas discharger 160 may individually, e.g., separately, supply vacuum to, e.g., each of, the first space S1 and the second space S2 to remove the contaminants from the first space S1 and the second space S2, e.g., the gas discharger 160 may separately discharge gas from each of the first space S1 and the second space S2. The gas discharger 160 may include a vacuum pump 162, a main exhaust line 164, at least one first exhaust line 166, and at least one second exhaust line 168. The main exhaust line 164 may be extended from the vacuum pump 162 to the preheating chamber 110. A manometer 180 for measuring the vacuum may be arranged on the main exhaust line 164.

The first exhaust line 166 may be branched from the main exhaust line 164. The first exhaust line 166 may be connected to the first space S1. For example, the first exhaust line 166 may be connected to the first space S1 through a sidewall of the preheating chamber 110. Thus, the vacuum may be introduced into the first space S1 through the first exhaust line 166 to remove the contaminants from the first space S1. For example, the first exhaust line 166 may include a single line. In another example, the first exhaust line 166 may include at least two lines.

As described above, because the first exhaust line 166 may be branched from the main exhaust line 164, the vacuum in the first exhaust line 166 may be substantially the same as the vacuum in the main exhaust line 164. Thus, the vacuum in the main exhaust line 164 and the first exhaust line 166 may be controlled using one manometer 172.

The second exhaust line 168 may be branched from the main exhaust line 164. The second exhaust line 168 may be connected to the second space S2. For example, the second exhaust line 168 may be connected to the second space S2 through the cooling plate 120. Alternatively, the second exhaust line 168 may be connected to the second space S2 through the isolation plate 140. Thus, the vacuum may be introduced into the second space S2 through the second exhaust line 168 to remove the contaminants from the second space S2. In detail, the contaminants in the second space S2 caused by the heater 130 may be discharged from the preheating chamber 110 through the second exhaust line 168 and the main exhaust line 164. Thus, the semiconductor substrate W may not be contaminated by the contaminants caused by the heater 130. For example, the second exhaust line 168 may include a single line. In another example, the second exhaust line 168 may include at least two lines.

As described above, because the second exhaust line 168 may be branched from the main exhaust line 164, the vacuum in the second exhaust line 168 may be substantially the same as the vacuum in the main exhaust line 164. Thus, the vacuum in the main exhaust line 164 and the second exhaust line 168 may be controlled using one manometer 172.

Further, because the first exhaust line 166 and the second exhaust line 168 may be branched from the main exhaust line 164, a pressure difference between the first space S1 and the second space S2 may be offset, e.g., substantially minimized. Thus, a damage of the isolation plate 140, which may be caused by the pressure difference between the first space S1 and the second space S2, may be prevented.

FIG. 4 is a cross-sectional view illustrating an apparatus for preheating a substrate in accordance with example embodiments.

A preheating apparatus 200 may include elements substantially the same as those of the preheating apparatus 100 in FIG. 3, except for a gas supplier and a gas discharger. Thus, the same reference numerals may refer to the same elements and any further descriptions with respect to the same elements may be omitted herein for brevity.

Referring to FIG. 4, the preheating apparatus 200 of example embodiments may include a first gas supplier 210, a second gas supplier 220, a first gas discharger 230, and a second gas discharger 240.

The first gas supplier 210 may supply the vent gas to the first space S1. The first gas supplier 210 may include a first vent gas tank 212 and a first gas line 214. The first vent gas tank 212 may store the vent gas. The first gas line 214 may be extended from the first vent gas tank 212. The first gas line 214 may be connected to the first space S1. For example, the first gas line 214 may be connected to the first space S1 through the cooling plate 120, the second space S2, and the isolation plate 140. A first manometer 250 may be arranged on the first gas line 214.

The second gas supplier 220 may supply the vent gas to the second space S2. The second gas supplier 220 may include a second vent gas tank 222 and a second gas line 224. The second vent gas tank 222 may store the vent gas. The second gas line 224 may be extended from the second vent gas tank 222. The second gas line 224 may be connected to the second space S2. For example, the second gas line 224 may be connected to the second space S2 through the cooling plate 120. A second manometer 252 may be arranged on the second gas line 224.

The first gas discharger 230 may supply the vacuum to the first space S1. The first gas discharger 230 may include a first vacuum pump 232 and a first exhaust line 234. The first exhaust line 234 may be extended from the first vacuum pump 232. The first exhaust line 234 may be connected to the first space S1. For example, the first exhaust line 234 may be connected to the first space S1 through the sidewall of the preheating chamber 110. A third manometer 254 may be arranged on the first exhaust line 234.

The second gas discharger 240 may supply the vacuum to the second space S2. The second gas discharger 240 may include a second vacuum pump 242 and a second exhaust line 244. The second exhaust line 244 may be extended from the second vacuum pump 242. The second exhaust line 244 may be connected to the second space S2. For example, the second exhaust line 244 may be connected to the second space S2 through the cooling plate 120. A fourth manometer 256 may be arranged on the second exhaust line 244.

According to example embodiments, the isolation plate may be combined with the cooling plate to form the first space and the second space isolated from each other. Thus, particles generated in the second space may not infiltrate into the first space. Further, the first gas line and the first exhaust line may be connected to the first space, and the second gas line and the second exhaust line may be connected to the second space, so that the particles in the first space and the second space may be individually discharged through the first exhaust line and the second exhaust line. As a result, the substrate may not make contact with the particles to prevent the substrate from being contaminated.

Further, because the first gas line and the second gas line may be branched from the main gas line, inner pressures of the first gas line and the second gas line may be controlled using only one manometer. Furthermore, because the first exhaust line and the second exhaust line may be branched from the main exhaust line, inner pressures of the first exhaust line and the second exhaust line may be controlled using only one manometer. Thus, an additional control mechanism for controlling the inner pressures may not be required.

By way of summation and review, an isolation plate may be arranged between the cooling plate with the lamp heater and the semiconductor substrate. In order to discharge the contaminants, a vent gas line and an exhaust line may be connected to the preheating chamber.

However, since an inner space of the preheating chamber may be divided into an upper space and a lower space by the isolation plate, while the upper space and the lower space are connected with each other, the vent gas may be moved from the upper space to the lower space, thereby moving contaminants, e.g., particles generated from the lamp heater, from the upper space to the lower space to contaminate the semiconductor substrate by the contaminants.

In contrast, example embodiments provide an apparatus for preheating a substrate without being contaminated by particles. That is, according to example embodiments, the isolation plate may be combined with the cooling plate to form the first space and the second space, e.g., completely, isolated from each other. Thus, particles generated in the second space may not infiltrate into the first space.

Further, the first gas line and the first exhaust line may be connected to the first space and the second gas line and the second exhaust line may be connected to the second space so that the particles in the first space and the second space may be individually discharged through the first exhaust line and the second exhaust line. As a result, the substrate may not make contact with the particles to prevent the substrate from being contaminated.

Further, because the first gas line and the second gas line may be branched from the main gas line, inner pressures of the first gas line and the second gas line may be controlled using only one manometer. Furthermore, because the first exhaust line and the second exhaust line may be branched from the main exhaust line, inner pressures of the first exhaust line and the second exhaust line may be controlled using only one manometer. Thus, an additional control mechanism for controlling the inner pressures may not be required.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An apparatus for preheating a substrate, the apparatus comprising:
a preheating chamber configured to receive the substrate;
a cooling plate in an upper portion of the preheating chamber;
a heater between the cooling plate and a bottom of the preheating chamber, the heater being configured to heat the substrate;
an isolation plate between the cooling plate and the bottom of the preheating chamber, the isolation plate defining a first space between the bottom of the preheating chamber and the isolation plate and a second space between the cooling plate and the isolation plate;
a gas supplier configured to separately supply a vent gas to each of the first space and the second space; and
a gas discharger configured to separately supply vacuum to each of the first space and the second space.

2. The apparatus as claimed in claim 1, wherein an edge portion of an upper surface of the isolation plate is combined with an edge portion of a lower surface of the cooling plate to define the second space.

3. The apparatus as claimed in claim 2, wherein:
the cooling plate includes a combining groove at the edge portion of the lower surface of the cooling plate, and
the isolation plate includes a combining portion inserted into the combining groove, the combining portion being at the edge portion of the upper surface of the isolation plate.

4. The apparatus as claimed in claim 1, wherein the gas supplier includes:
a main gas line configured to supply the vent gas into the preheating chamber;
at least one first gas line connected between the main gas line and the first space; and
at least one second gas line connected between the main gas line and the second space.

5. The apparatus as claimed in claim 4, wherein the first gas line is connected to the first space through the cooling plate and the isolation plate.

6. The apparatus as claimed in claim 4, wherein the second gas line is connected to the second space through the cooling plate.

7. The apparatus as claimed in claim 1, wherein the gas discharger includes:
a main exhaust line configured to supply the vacuum into the preheating chamber;
at least one first exhaust line connected between the main exhaust line and the first space; and
at least one second exhaust line connected between the main exhaust line and the second space.

8. The apparatus as claimed in claim 7, wherein the first exhaust line is connected to the first space through a sidewall of the preheating chamber.

9. The apparatus as claimed in claim 7, wherein the second exhaust line is connected to the second space through the cooling plate.

10. The apparatus as claimed in claim 1, wherein the heater is on a lower surface of the cooling plate.

11. The apparatus as claimed in claim 1, wherein the heater includes a lamp heater.

12. The apparatus as claimed in claim 1, wherein the isolation plate includes quartz.

13. The apparatus as claimed in claim 1, wherein the heater is configured to heat the substrate before an ion implantation process.

14. An apparatus for preheating a substrate, the apparatus comprising:
a preheating chamber configured to receive the substrate before an ion implantation process;
a cooling plate in an upper portion of the preheating chamber;
a heater between the cooling plate and a bottom of the preheating chamber, the heater being configured to heat the substrate;
an isolation plate between the cooling plate and the bottom of the preheating chamber, the isolation plate being combined with an edge portion of a lower surface of the cooling plate and defining a first space between the bottom of the preheating chamber and the isolation plate and a second space between the cooling plate and the isolation plate;
a gas supplier configured to separately supply a vent gas to each of the first space and the second space; and
a gas discharger configured to separately supply vacuum to each of the first space and the second space,
wherein the gas supplier includes:
a main gas line configured to supply the vent gas into the preheating chamber;
at least one first gas line connected between the main gas line and the first space; and
at least one second gas line connected between the main gas line and the second space, and
wherein the gas discharger includes:
a main exhaust line configured to supply the vacuum into the preheating chamber;
at least one first exhaust line connected between the main exhaust line and the first space; and
at least one second exhaust line connected between the main exhaust line and the second space.

15. The apparatus as claimed in claim 14, wherein:
the cooling plate includes a combining groove at the edge portion of the lower surface of the cooling plate, and
the isolation plate includes a combining portion inserted into the combining groove, the combining portion being at an edge portion of an upper surface of the isolation plate.

16. The apparatus as claimed in claim 14, wherein the first gas line is connected to the first space through the cooling plate and the isolation plate, and the second gas line is connected to the second space through the cooling plate.

17. The apparatus as claimed in claim 14, wherein the first exhaust line is connected to the first space through a sidewall of the preheating chamber, and the second exhaust line is connected to the second space through the cooling plate.

18. The apparatus as claimed in claim 14, wherein the heater includes a lamp heater.

19. An apparatus for preheating a substrate, the apparatus comprising:
a preheating chamber configured to receive the substrate;
a cooling plate in an upper portion of the preheating chamber;
a heater between the cooling plate and a bottom of the preheating chamber, the heater being configured to heat the substrate;
an isolation plate between the cooling plate and the bottom of the preheating chamber, the isolation plate defining a first space between the bottom of the preheating chamber and the isolation plate and a second space between the cooling plate and the isolation plate;
a first gas supplier configured to supply a vent gas to the first space;
a second gas supplier configured to supply the vent gas to the second space;
a first gas discharger configured to supply a vacuum to the first space; and
a second gas discharger configured to supply the vacuum to the second space.

20. The apparatus as claimed in claim 19, wherein:
the first gas supplier includes a first gas line connected to the first space, the second gas supplier includes a second gas line connected to the second space,
the first gas discharger includes a first exhaust line connected to the first space, and
the second gas discharger includes a second exhaust line connected to the second space.
